(19) United States
(12) Patent Application Publication
(10) Pub. No.: US 2006/0290404 A1
(43) Pub. Date: Dec. 28, 2006

(54) APPARATUS AND METHODS FOR VOLTAGE LEVEL CONVERSION

(75) Inventor: Oscar M.K. Law, Markham, Ontario (CA)

Correspondence Address: VEDDER PRICE KAUFMAN & KAMMHOLZ, 222 N. LASALLE STREET, CHICAGO, IL, 60601, US

(73) Assignee: ATI TECHNOLOGIES INC., Markham, Ontario (CA)

(21) Appl. No.: 11/160,435

(22) Filed: Jun. 23, 2005

(51) Int. Cl. H03L 5/00

(52) U.S. Cl. 327/333

(57) ABSTRACT

A cross-coupled, latching voltage level converter to convert a signal from a first voltage domain to a second voltage domain and hold an output logic level is disclosed. The converter includes back-to-back first and second inverter circuits coupled to a first voltage source operable at a first voltage level. A transistor is coupled between an output of the first inverter and ground potential, the first transistor having a gate coupled to an input signal operable at a second voltage level. A second transistor is coupled between the output of the second inverter and ground potential, the second transistor having a gate coupled to an inverse of the input signal operable at the second voltage, wherein a terminal of the second transistor delivers an output signal operable at the first voltage level and corresponding to the same logic state as the input signal.

The present disclosure relates to methods and apparatus for voltage level conversion and, more particularly, for voltage level conversion between blocks within a discrete or integrated circuit, including full custom circuits, application specific integrated circuits (ASIC), and field programmable gate arrays (FPGAs).

### BACKGROUND

Increasingly in circuits, such as integrated circuits, the number of transistors integrated in large-scale increases with each generation of integrated circuits. With even larger scale integration, the power requirements for such circuits also increase, accordingly. As the technology advances, semiconductor device sizes are also reduced, leading to higher leakage due to smaller geometric features, such as thinner gate oxide layers and shorter channel lengths, as examples. The overall amount of power leakage in these circuits becomes comparable to the amount of active power, and, thus, cannot be ignored during circuit development. In order to reduce the power and leakage of these circuits, the voltage levels at which the circuits operate have been reduced.

In order to mitigate power leakage, in some integrated circuits, in particular, circuits within the integrated circuit are partitioned into different domains or islands according to the functions performed by the transistors in each domain. Accordingly, depending on the particular functions, the voltage levels in some domains are set higher than voltages in other domains where either the frequency is lower or the performance is less critical. As a result, the total power and power leakage are significantly reduced due to different voltage levels, particularly by using lower voltages. This methodology is commonly referred to as Multiple Voltage Supply (MVS) or Voltage Island approach.

The voltage domains in MVS or Voltage Island approach, nonetheless, typically transmit binary data between one another with a resultant voltage gap difference in the signals. Accordingly, level conversion circuits are needed to convert or translate from one voltage domain to another voltage domain.

An example of this type of integrated circuit construction is illustrated in FIG. 1. As shown, an integrated circuit 100 includes a number of voltage domains or islands 104, 106, 108, and 110. In order to account for the voltage gap differences between the different voltage domains when signaling via connections 112, for example, a number of voltage level converters 114 are included in these connections 112 in order to either step up or step down the signaling voltages to translate from one domain to another.

FIG. 2 illustrates an example of a level converter 114. Level converter 114, in particular, includes a differential voltage level converter 200, which translates signals between different voltage domains (e.g., 106 and 110). As illustrated, the differential voltage level converter 200 receives an input signal 202 (IN), which is connected to a gate of an NMOS transistor 204. The input signal 202 is operable between zero volts and a voltage VDDL, the former being a logic state “0” and the latter being a logic state “1.” The transistor 204 is connected in series with a PMOS transistor 206, having a source connected to a voltage VDDH, which is equivalent to the operating voltage of a voltage domain, such as voltage domain 110, as an example. For purposes of this example, the voltage level converter 114 is connected between voltage domain 106 and voltage domain 110, which are assumed to operate at different voltages. For example, voltage domain 106 may operate at 0.5 volts whereas voltage domain 110 has an operating voltage of 1.0 volt.

The differential voltage level converter 200 also includes another PMOS transistor 208 connected to the source voltage VDDH of voltage domain 110 and having a gate coupled to the drain of transistor 206. Additionally, as shown, the gate of transistor 206 is connected to a drain of transistor 208. Another NMOS transistor 210 is connected in series with transistor 208 and has a gate connected to an inverse (indicated by a bar over the signal name) signal 212 ( ) of the input signal 202, which may be derived via an inverter (not shown) connected between the input signal 202 and the inverse signal input 212 in order to obtain the inverse.

Accordingly, for purposes of describing operation of the converter 200, it is assumed that the input 202 is at a logic level “1”, which would be VDDL=0.5 volts assuming the parameters of this particular example. When a logic level is “1”, transistor 204 is turned on and an inverse output node 214 becomes low or logic level “0” since the node at 214 is connected to ground (or some other common potential) by transistor 204. In the differential counterpart (i.e., transistors 208, 210), the transistor 210 is off and transistor 208 is turned on due to a low input at its gate. Thus, an output 216 is high or logic level “1,” but at voltage level VDDH. Thus, the input logic state at 202 is mirrored at the output 216, but amplified to a higher voltage level. Both transistor 206 and 208 form the feedback path to speed up the conversion process and amplify the output 206 to full voltage swing (VDDH). It is noted that although the example of FIG. 2 illustrates a conversion from a low voltage VDDL to a high voltage VDDH, the same circuitry can be used to convert from high voltage to low voltage by connecting an input signal from a higher voltage island to the input 202 yielding an attenuated output at the lower voltage VDDL. Accordingly, separate voltage converters 114 are needed for translating signals from a lower voltage domain, such as domain 106 in the present example, to a higher voltage domain 110 and another level converter 114 is needed for translating signals sent from a higher voltage domain to a lower voltage domain.

In order to reduce the power usage of integrated circuits such as ASICs, it is also known to shut down a particular voltage domain or island. However, when the voltage domain that is shut down is connected to an input of the differential voltage level converter 200, the inverse output node 214 gradually starts to float and gradually increases to an intermediate voltage level (e.g., a voltage level somewhere between 0 and VDDH), resulting in an indefinite or incorrect logic output on the output 216. Thus, when the other voltage domain (e.g., voltage domain 110) requires a particular logic state to be presented on the output 216 or 214, regardless of the operational state of the other voltage domain (e.g., voltage domain 106), errors occur due to the incorrect logic state of the output 216.

In order to solve this problem, it is known to include a separate keeper circuit 218 connected to the output 216 of the differential voltage level converter 200 in order to maintain or preserve data when the input voltage is not present or operational. The example illustrated in FIG. 2 shows a keeper circuit 218 that includes a pair of voltage inverters 220 and 222 connected to either VDDH or another voltage supply VDDC, as shown. These inverters 220, 222 are connected also to a transmission gate 224. Essentially, the keeper circuit 218 is a simple latch that preserves the logic input to the inverters 220, 222 by the transmission gate 224. Such keeper circuits 218, however, utilize about 12 transistors, which in turn take up valuable area on circuit 100. Additionally, the use of more transistors increases the power usage of the circuit.

### BRIEF DESCRIPTION OF THE DRAWINGS

FIG. 1 illustrates an example of an integrated circuit utilizing multiple voltage domains.

FIG. 2 illustrates an example of the voltage level conversion circuit that may be used in the integrated circuit of FIG. 1.

FIG. 3 illustrates an example of a cross-coupled level converter in accordance with the present disclosure that may be utilized in the integrated circuit of FIG. 1.

FIG. 4 illustrates an example of a circuit diagram of the cross-coupled level converter of FIG. 3.

FIG. 5 illustrates an exemplary block diagram of a two-stage level converter according to the present disclosure.

FIG. 6 illustrates an exemplary circuit diagram of the two-stage level converter circuit of FIG. 5.

FIG. 7 illustrates another example of a two stage level converter in accordance with the present disclosure.

FIG. 8 illustrates a further example of a two-stage converter with an enable circuit according to the present disclosure.

FIG. 9 illustrates another example of a two stage level converter with an enable circuit in accordance with the present disclosure.

FIG. 10 illustrates an example of a two stage level converter with a clock circuit in accordance with the present disclosure.

FIG. 11 illustrates an example of a method in accordance with the present disclosure.

### DETAILED DESCRIPTION

The present disclosure relates to apparatus for level conversion between different voltage domains within circuits, such as discrete or integrated circuits (e.g., ASICs and CPUs). A particular apparatus includes a first inverter circuit coupled to a first voltage source operable at a first voltage level, and a second inverter circuit also coupled to the first voltage source and coupled to the first inverter such that an output of the first inverter is coupled to an input of the second inverter and an output of the second inverter is coupled to an input of the first inverter, also known as a “back-to-back” feedback closed loop connection. The apparatus also includes a first transistor coupled between an output of the first inverter and a common potential where the first transistor has a terminal coupled to an input signal operable at a second voltage level. The apparatus also includes a second transistor coupled between the output of the second inverter and a common potential, the second transistor having a terminal coupled to an inverse of the input signal operable at the second voltage where the terminal of the second transistor delivers an output signal operable at a first voltage level and corresponding to the same logic state as the input signal.

The disclosed apparatus serves to perform voltage level conversion as well as hold a particular voltage level when the supply voltage of the voltage domain supplying the input signal to the level converter is not operating or, in other words, turned off. Thus, the apparatus affords level conversion while preserving data at the input on the output with a minimum number of transistors thereby reducing the area on the integrated circuit. Additionally, because fewer transistors are utilized to achieve level conversion as well as holding a logic state, the amount of power used for this function is further reduced.

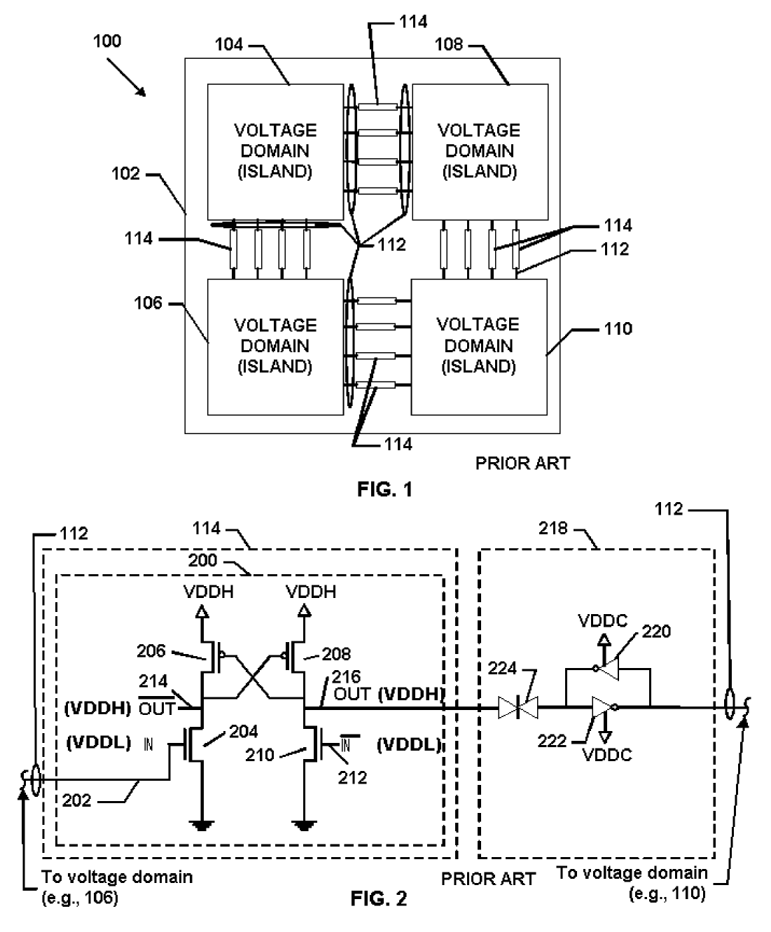

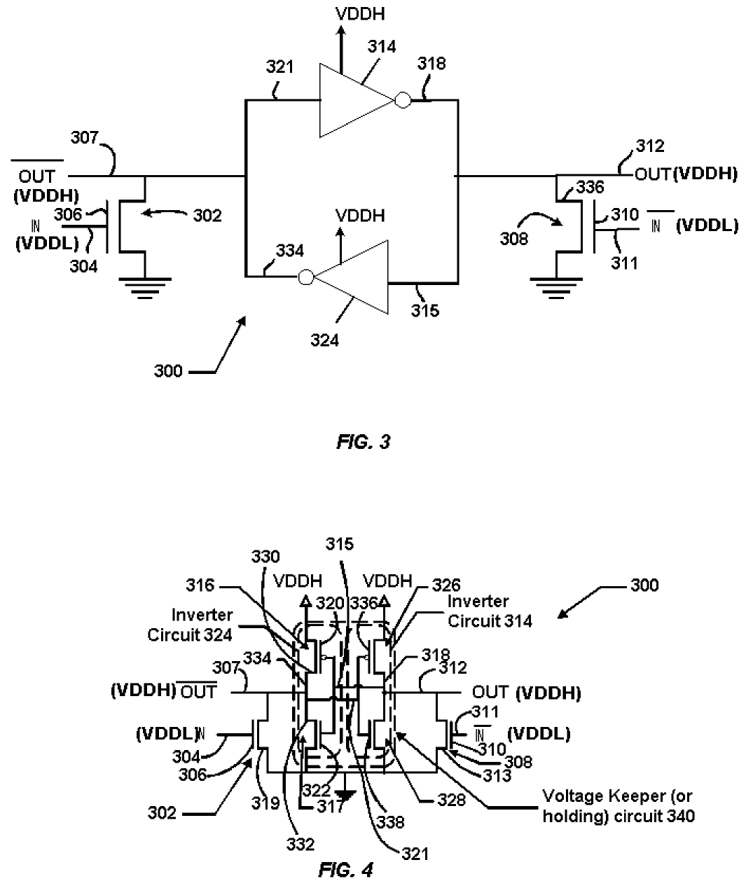

FIG. 3 illustrates an example of a cross-coupled, static latch level converter apparatus 300 in accordance with the present disclosure that may be utilized within the integrated circuit of FIG. 1. The apparatus 300 includes a first inverter circuit 314 connected to a first voltage source operable at a first voltage level (VDDH) as shown in FIG. 3. Apparatus 300 also includes a second inverter circuit 324 also connected to the first voltage source VDDH and connected to the first inverter 314 such that an output 318 of the first inverter 314 is connected to an input 315 of the second inverter 324 and an output 334 of the second inverter 324 is connected to an input 321 of the first inverter 314. This connection arrangement is also known as a “back-to-back” feedback closed loop connection, where the logic state is maintained inside the closed loop without any changes.

Apparatus 300 also includes a first input transistor 302 connected between an inverse output ( ) 307 (which is connected to the output 334 of the second inverter 324) and a common potential such as ground potential where the first transistor 302 has a gate terminal 306 connected to an input signal (IN) 304 operable at a second voltage level VDDL. The apparatus 300 also includes a second input transistor 308 connected between an output 312 (OUT), which is connected to the output 318 of the first inverter 314, and ground potential, the second transistor having a gate terminal 310 connected to an inverse ( ) 311 of the input signal 304 operable at the second voltage VDDL where a terminal 336 of the second transistor 308 delivers an output signal 312 operable at the first voltage level and corresponding to the same logic state as the input signal 304.

FIG. 4 illustrates an exemplary circuit diagram of the cross-coupled level converter of FIG. 3. This illustration uses the same references numbers to illustrate the same elements as those shown in FIG. 3. As illustrated, the exemplary circuit 300 shown in FIG. 4 uses a CMOS process. It is noted, however, that this circuit is only an example and the level converter can be applied for various semiconductor processes including, but not limited to, CMOS, NMOS, GaAs, SOI and SeGe processes.

The illustrated level conversion circuit 300 includes the input transistor 302, which is a pull-down transistor having a drain 319 connected to ground potential. As shown, input signal 304 is connected to the gate 306 of the transistor 302. Thus, when the logic state of the input signal 304 is high, transistor 302 turns on and pulls the inverse output 307 down to ground potential. Input signal 304 is operable at logic states between 0 volts (representing a binary “0”) and voltage VDDL (representing a binary “1”). Circuit 300, however, is also operable having an input from a higher voltage domain (VDDH) for conversion or translation to a lower voltage domain (VDDL).

Similarly, pull-down transistor 308 has its gate 310 connected to the inverse input signal 311, which may be achieved by connecting an inverter (not shown), for example, between the input 304 and inverse input 311. Operation of the transistor 308 serves to pull the logic level at output 312 to ground potential via a drain 313 connected to ground.

FIG. 4 illustrates the voltage level converter circuit 300 also including the first inverter circuit 314 connected to voltage VDDH. The inverter circuit 314 includes a PMOS transistor 326 connected in series with an NMOS transistor 328. Output 318 between transistor 326 and transistor 328 is connected to the output 312 of the circuit 300, which is also connected to the input 315 of the second inverter circuit 324. Additionally, the gates of the transistors 326 and 328 (respectively 336 and 338) are connected to one another and comprise the input 321 of the inverter 324.

The illustrated voltage level conversion circuit 300 in FIG. 4 also shows the second inverter 324 including a PMOS transistor 316 and an NMOS transistor 317 connected in series between voltage VDDH and ground. The junction or node 334 connecting a drain 330 of transistor 316 and a source 332 of transistor 317 comprises the output of the second inverter circuit 324 and is connected to the inverse output 307 of the voltage level conversion circuit 300. The gates of transistors 316 and 317 (320 and 322, respectively), which are the input 315 of the second inverter circuit 324 are connected together and collectively connect to the output connection point 318 of the first inverter circuit 314 and the output 312 of the circuit 300.

The inverters 314 and 324 may also be characterized as a keeper or a voltage holding circuitry 340, which serves to maintain the logic state on the output 312 when the input signal 304 is off or not operable in the case where a voltage domain operating at VDDL is turned off. The inverters 314 and 324 are still functional for the purpose of maintaining the logic state of output 312 as they are maintained by the still present voltage VDDH of another voltage domain. In particular, regardless of the voltage state of the input 304, the state of the output 312 is maintained due to the back-to-back connection of the inverters 314 and 324, thereby latching the output state.

In operation, the circuit of FIGS. 3 and 4 mirrors the logic state of the input 304 at the output 312. For example, when the input 304 is at a logic state “1” (i.e., equal to 0.5 volts as the VDDL, for example) the state of the inverse output 307 is zero or low since transistor 302 is turned on pulling the voltage of the inverse output 307 to ground. Accordingly, the logic level at the input 321 of the first inverter 314, is zero or low, causing PMOS transistor 326 to turn on and NMOS transistor 328 to turn off. The logic level at output 318 of the first inverter 314 is then high. Also, because output 318 is also connected to the input 315 of second inverter 324, transistor 316 is turned off and transistor 317 is turned on. Additionally, the transistor 308 is turned off as the inverse of the input signal 304 is low. Accordingly, the output 312 is high or a logic binary value of “1,” thus mirroring the input logic state 304.

As illustrated above, the level conversion circuit 300 of FIG. 3 serves to effect level conversion, while also keeping or holding the output voltage when the input voltage source (e.g., VDDL) is not operating or off with the use of six total transistors. This circuit arrangement 300 serves to carry out these functions while occupying minimal area, as well as drawing a lesser amount of power, thereby economizing chip size and power consumption. It is also noted that although the circuit 300 of FIG. 3 illustrates a particular combination of PMOS and NMOS transistors, one of ordinary skill in the art will appreciate that various other combinations of PMOS and NMOS transistors could be used, as well as different types of suitable transistors.

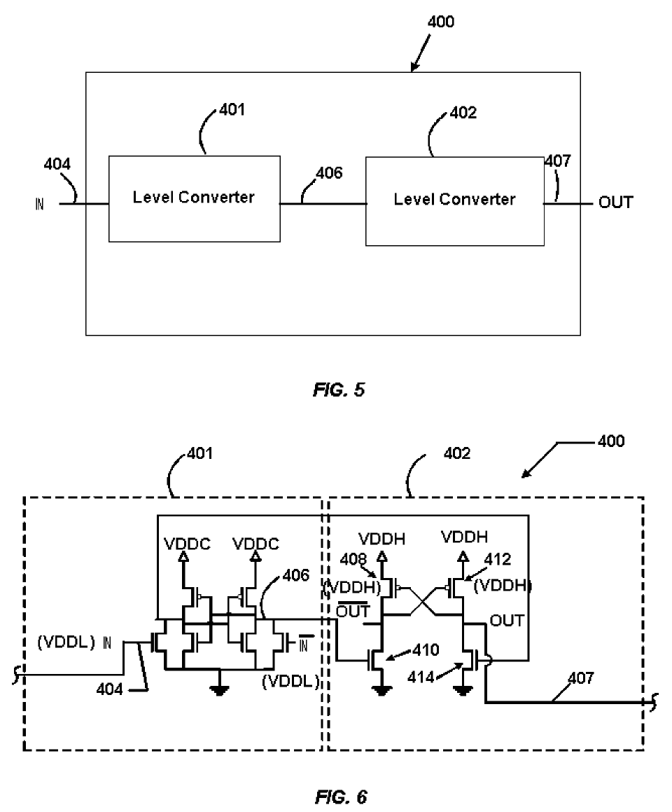

Situations also may arise within a circuit employing multiple voltage domains when both the voltage domain at the input of a level converter and the voltage domain connected to an output of the level converter are powered down at the same time. Thus, in such situations the VDDL and VDDH voltages are not present and the inverter circuits 314 and 324 of FIG. 3, for example, would not have power in which to maintain or keep the output logic level state. Accordingly, upon re-powering up of one or both of the voltage domains, the integrity of the logic state on the output (e.g., 312) is not maintained. In this case, an additional voltage supply, as well as a two-stage level converter may be used to ensure logic state integrity on the output. An example of such a circuit is illustrated in FIGS. 5 and 6.

As illustrated in FIG. 5, a two-stage voltage level conversion circuit 400 is illustrated, having a first level converter 401, which is similar to the circuit of FIGS. 3 and 4, and a second level converter 402, which can be either a differential or cross coupled level converter. An input 404 is fed to first level converter 401 with a first supply voltage and then passes an output 406 to second level converter 402 with a second supply voltage, resulting in output 407.

In FIG. 5, two stage level converter 400 may be implemented using CMOS process. In particular, FIG. 6 illustrates an exemplary implementation of the circuit of FIG. 5. As illustrated, the first stage 401 has the same circuit architecture as the cross coupled level converter 300 of FIGS. 3 and 4, but the inverters are powered using a third, separate voltage source VDDC, which is constantly maintained. Thus, when voltage domains employing voltages VDDL and VDDH are shut down, the back-to-back inverters (e.g., 314 and 324) maintain the last logic state of the input 404 at the output 406 of the first stage level converter 401.

Furthermore, in order to ensure that the output 407 of the second stage level converter 402 correctly translates the output state at 406, which is operable with voltage VDDC, to the voltage level VDDH of the voltage domain to which it is connected, the second stage 402 employs a differential voltage level converter including four transistors 408, 410, 412, 414 operating similar to the prior art differential converter 200 illustrated in FIG. 2. Thus, the circuit 400 ensures that that upon re-powering up of two voltage domains, the correct voltage state of output 406 is delivered to output 407.

FIG. 7 illustrates an alternative example of a two-stage level converter circuit 500 where, instead of using a differential level converter, such as the second stage converter 402 in FIG. 4, a second stage 502 utilizes a cross-coupled static latch converter identical to the a first stage 504 to accomplish the same functionality as the circuit of FIGS. 5 and 6, for example. The first and second stages 502, 504 of circuit 500 have the identical architecture as the level converter 300 in FIGS. 3 and 4, but utilize an additional, constant source of voltage VDDC as the two-stage converter in FIG. 6.

FIG. 8 illustrates another example of a two stage level converter 600, which is similar to the circuit shown in FIGS. 5 and 6. In the circuit of FIG. 8, however, an additional enable transistor 602 is included connected to the drains 604 and 606 of first and second pull down transistors 608 and 610. An enable signal 612 is input to a gate 614 of the enable transistor 602. The voltage source supplying the enable signal 612 is a third voltage source VDDC, which ensures that the voltages operational when the voltage domains connected to the level conversion circuit 600 or turned off or not operational. The addition of the enable transistor 602 allows control of the pull down transistors 608 and 610 such that the level conversion circuit only provides an output signal in response to an input signal when the signal 612 is high, thus connecting the drain 604 and 606 to ground potential through transistor 602. This design affords a reduction in the power usage of the level conversion circuit 600 since the operation of the circuit may be controlled by the enable transistor 602. Additionally, this design functions to limit level conversion operations, which results in reduced power consumption by latching the output when the enable signal 612 is high, thus limiting the level conversion operation and resulting in less power consumption.

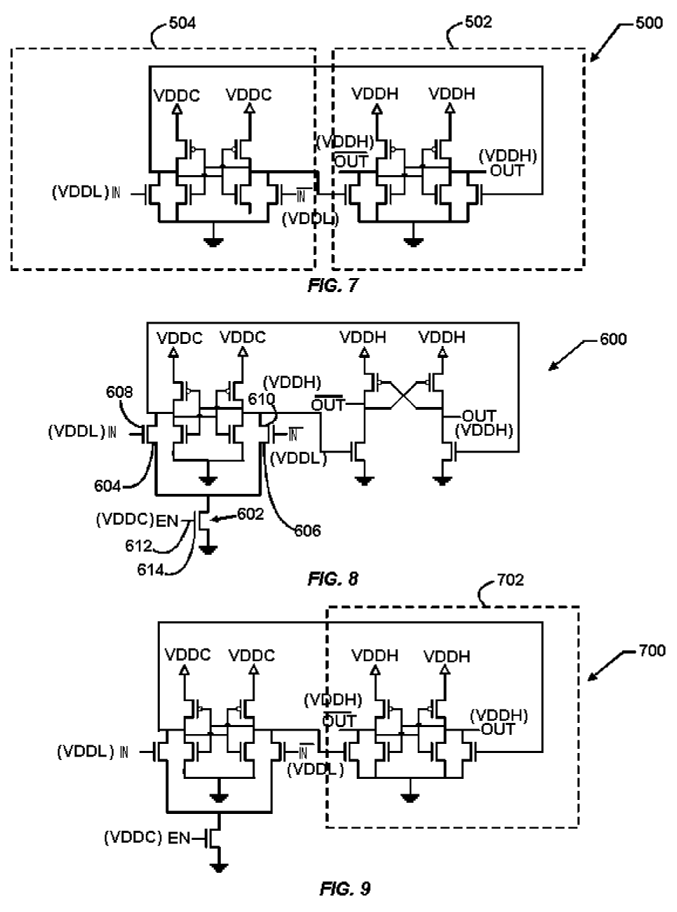

FIG. 9 illustrates another example of a two-stage level conversion circuit 700 having an enable signal input similar to the circuit of FIG. 8. Rather than the second stage consisting of a differential voltage level converter as shown in FIG. 8, the second stage 702 of the level converter 700 utilizes a cross coupled conversion latch circuit as explained in FIG. 3.

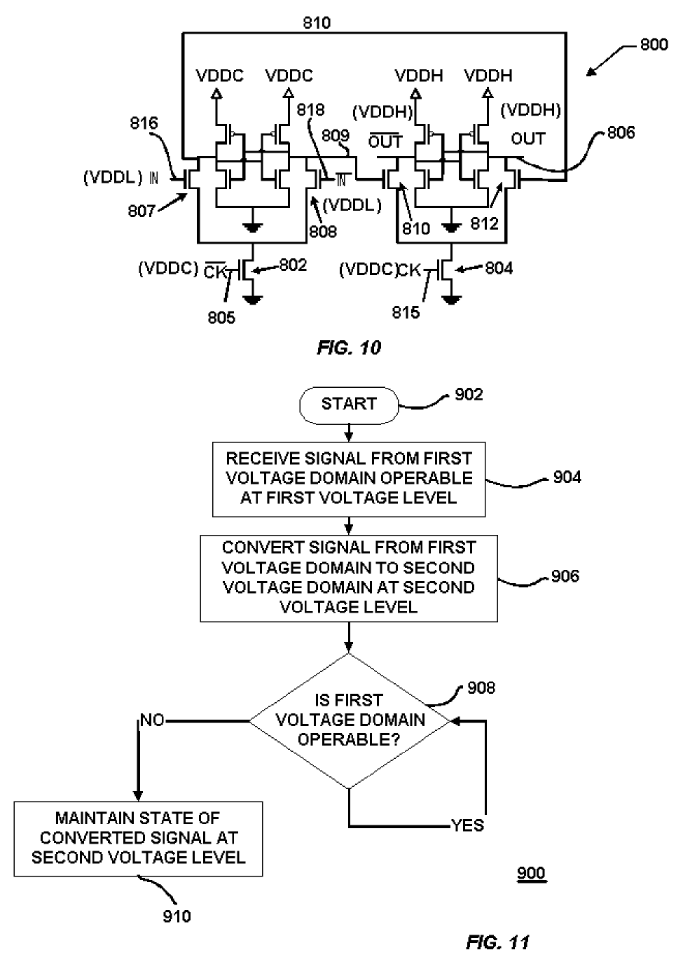

FIG. 10 illustrates another example of a level conversion circuit 800 including a pair of clocking transistors 802, 804 where use of the clocking transistors 802 and 804 allows the level conversion circuit 800 to function as a flip flop circuit where the conversion circuit becomes operational on a rising edge of the clock signal 815 input to the gate of transistor 804. In particular, the circuit 800 illustrated in FIG. 10 functions as a “D” flip flop where the output 806 is latched to a particular logic state after a rising edge of the clock signal and will not be capable of being changed until a next rising edge of the clock signal.

As illustrated, the clocking transistor 802 is connected to an inverse of clock signal 805 and is connected between ground potential and the drains of pull down transistors 807 and 808 in a first stage of the conversion circuit. The clocking transistor 804, connected to the clock signal 815, is also connected between ground and the drains of transistors 810 and 812 in a second stage cross-coupled level converter.

In operation, when the clock signal 815 is low, the inverse clock signal 805 is high, the clocking transistor 802 is turned on, the input signals 816 and 818 are latched in a first level converter. Conversely, when the clock signal 815 is high, the input signals 807 and 808 are disabled. Thus, when signal 815 is high, it turns on clocking transistor 804, and the output of first level converter 809 is fed to the second level converter. Thus, two stage level converter functions as D flip flop to latch the input signal 816 signal based on the clock transition. The circuit of FIG. 10, among other things, affords power reduction through reducing the operation of either first or second stages of the converter circuit 800 during particular time periods.

FIG. 11 is an exemplary flow diagram illustrating a method in accordance with the present disclosure for level conversion of signal from one voltage domain to a second voltage domain. As shown, the method starts at a block 902 and flow proceeds to block 904. At block 904, a signal such as signal 304 shown in FIG. 3, from the first voltage domain (e.g., VDDL) is received. Through the use of back to back inverters in FIG. 3, as an example, the voltage level of the signal is converted to the second voltage level (e.g., VDDH) of the second voltage domain, as indicated at block 906. Next, while the first voltage domain remains operable, the latching characteristic of the back-to-back inverters (e.g., 314, 324) is not utilized as indicated at decision block 908. In other words, as long as the first voltage level is operable, the circuit will not latch or hold the signal from the first voltage domain since the output can change with each change in the input signal. Alternatively at block 908, when the first voltage domain is shut down or not operable, the latching characteristic of the back to back inverters holds or maintains the converted signal state that has been converted to the second voltage domain as indicated in block 910.

In light of the foregoing, the disclosed apparatus, and methods by utilizing back-to-back converters along with pull down transistors affords the preservation of an output logic state of the converter circuit when a particular voltage domain is turned off with a reduction in the space needed on the ASIC. Additionally, because fewer transistors are used than, conventional level conversion circuits as an example, the power consumption is further reduced. These features are useful across many applications including desktop, portable or laptop computers, hand held devices such as PDAs and cell phones, as well as consumer products in order to reduce size and save power.

The above detailed description of the examples has been presented for the purposes of illustration and description only and not by limitation. It is therefore contemplated that the present application cover any additional modifications, variations, or equivalents that fall within the spirit and scope of the basic underlying principles disclosed above and the appended claims.

What is claimed is:

1. A voltage level converter comprising:
a first inverter circuit coupled to a first voltage source operable at a first voltage level;
a second inverter circuit coupled to the first voltage source and coupled to the first inverter such that an output of the first inverter is coupled to an input of the second inverter and an output of the second inverter is coupled to an input of the first inverter;
a first transistor coupled between an output of the second inverter circuit and a common potential, the first transistor having a terminal coupled to an input signal operable at a second voltage level; and
a second transistor coupled between the output of the first inverter circuit and the common potential, the second transistor having a terminal coupled to an inverse of the input signal operable at the second voltage level, wherein another terminal of the second transistor delivers an output signal operable at the first voltage level and corresponding to the same logic state as the input signal.

2. The voltage level converter as defined in claim 1, wherein the first inverter circuit includes third and fourth transistors with a terminal of the third transistor coupled to a terminal of the fourth transistor at a first node and the second inverter circuit includes fifth and sixth transistors having a terminal of the fifth transistor coupled to a terminal of the sixth transistor at a second node, where the first and second inverter circuits are operable to hold a logic level on the output when the second voltage supply is not operating.

3. The voltage level converter circuit as defined in claim 2, further comprising:
a second voltage converter coupled to the output of the first inverter circuit and to a third voltage source operable at a third voltage level, wherein the logic level held by the first and second inverter circuits is accurately translated to an output of the second voltage converter after the second and third voltage sources are operable after being not operable.

4. The voltage level converter circuit as defined in claim 3, further comprising:
an enable transistor having a terminal coupled to terminals of the first and second transistors, another terminal coupled to ground, and a gate coupled to an enable signal operable with the third voltage source, wherein operation of the level converter circuit may be switched on and off by operation of the enable transistor.

5. The voltage level converter circuit as defined in claim 3, further comprising:
at least one clocking transistor having a having a terminal coupled to terminals of the first and second transistors, another terminal coupled to ground, and a gate coupled to a clock signal operable with the third voltage source, wherein operation of the level converter circuit may be switched on and off by operation of the at least one clocking transistor.

6. A voltage level converter comprising:
a converter output;
a first transistor having a gate terminal coupled to an input signal from a first voltage domain in an integrated circuit operable at logic states between zero and a first voltage level of a first voltage source;
a second transistor having a gate terminal coupled to an inverse of the input signal and including another terminal coupled to the converter output, which is coupled to a second voltage domain in the integrated circuit and operable at a second voltage level from a second voltage source; and
a voltage holding circuit coupled between terminals of the first and second transistors and coupled to the second voltage source, the voltage holding circuit operable to maintain a voltage state on the output when the first voltage source is not operable.

7. The voltage level converter as defined in claim 6, wherein the voltage holding circuit further comprises:
a first inverter circuit having an output coupled to converter output, the first inverter circuit including third and fourth transistors coupled in series and each having a gate terminal coupled to a terminal of the first transistor; and
a second inverter circuit having an output coupled to the terminal of the first transistor, the second inverter circuit including fifth and sixth transistors coupled in series and each having a gate terminal coupled to the inverse converter output.

8. The voltage level converter as defined in claim 6, further comprising:
a second stage level converter having an input coupled to the converter output, the second stage level converter including:
a seventh having a gate comprising the input coupled to the converter output and a terminal coupled to a second stage level converter output
an eighth transistor having a gate coupled to an inverse of the converter output and a terminal coupled to a second stage level converter output;
at least a ninth transistor having a gate coupled to the second stage level converter output and a terminal coupled to a third voltage source; and
at least a tenth transistor having a gate coupled to second stage level converter output and a terminal coupled to the third voltage source;
wherein the second stage level converter is configured such that a logic level of the converter output is accurately translated to the second stage level converter output after the second and third voltage sources are operable after being not operable.

9. The voltage level converter as defined in claim 8, further comprising:
an enable transistor having a terminal coupled to terminals of the first and second transistors, another terminal coupled to a common potential, and a gate terminal coupled to an enable signal operable with the second voltage source, wherein operation of the level converter may be switched on and off by operation of the enable transistor.

10. The voltage level converter as defined in claim 8, further comprising:
at least one clocking transistor having a having a terminal coupled to terminals of the first and second transistors, another terminal coupled to a common potential, and a gate coupled to a clock signal operable with the third voltage source, wherein operation of the level converter may be switched on and off by operation of the at least one clocking transistor.

11. The voltage level converter as defined in claim 7, wherein the first, second, fourth and sixth transistors are NMOS transistors, and the third and fifth transistors are PMOS transistors.

12. An integrated circuit comprising:
at least first and second areas operating at respective first and second voltage levels; and
at least one voltage level converter for converting voltage levels of signals passing between the first and second areas, the voltage level converter including:
a first inverter circuit coupled to a first voltage source operable at the first voltage level;
a second inverter circuit coupled to the first voltage source and coupled to the first inverter such that an output of the first inverter is coupled to an input of the second inverter and an output of the second inverter is coupled to an input of the first inverter;
a first transistor coupled between an output of the second inverter circuit and a common potential, the first transistor having a terminal coupled to an input signal operable at the second voltage level; and
a second transistor coupled between the output of the first inverter circuit and the common potential, the second transistor having a terminal coupled to an inverse of the input signal operable at the second voltage level, wherein another terminal of the second transistor delivers an output signal operable at the first voltage level and corresponding to the same logic state as the input signal.

13. The integrated circuit as defined in claim 12, wherein the first inverter circuit includes third and fourth transistors with a terminal of the third transistor coupled to a terminal of the fourth transistor at a first node and the second inverter circuit includes fifth and sixth transistors having a terminal of the fifth transistor coupled to a terminal of the sixth transistor at a second node, where the first and second inverter circuits are operable to hold a logic level on the output when the second voltage supply is not operating.

14. The integrated circuit as defined in claim 13, further comprising:
a second voltage converter coupled to the output of the first inverter circuit and to a third voltage source operable at a third voltage level, wherein the logic level held by the first and second inverter circuits is accurately translated to an output of the second voltage converter after the second and third voltage sources are operable after being not operable.

15. The integrated circuit as defined in claim 14, further comprising:
an enable transistor having a terminal coupled to terminals of the first and second transistors, another terminal coupled to ground, and a gate coupled to an enable signal operable with the third voltage source, wherein operation of the level converter circuit may be switched on and off by operation of the enable transistor.

16. The integrated circuit as defined in claim 14, further comprising:
at least one clocking transistor having a having a terminal coupled to terminals of the first and second transistors, another terminal coupled to ground, and a gate coupled to a clock signal operable with the third voltage source, wherein operation of the level converter circuit may be switched on and off by operation of the at least one clocking transistor.

17. An integrated circuit comprising:
at least first and second areas operating at respective first and second voltage levels; and
at least one voltage level converter for converting voltage levels of signals passing between the first and second areas, the voltage level converter including:
a converter output
a first transistor having a gate terminal coupled to an input signal from a first voltage domain in an integrated circuit operable at logic states between zero and the first voltage level of a first voltage source;
a second transistor having a gate terminal coupled to an inverse of the input signal and including another terminal coupled to the converter output, which is coupled to a second voltage domain in the integrated circuit and operable at the second voltage level from a second voltage source; and
a voltage holding circuit coupled between terminals of the first and second transistors and coupled to the second voltage source, the voltage holding circuit operable to maintain a voltage state on the output when the first voltage source is not operable.

18. The integrated circuit as defined in claim 17, wherein the voltage holding circuit further comprises:
a first inverter circuit having an output coupled to converter output, the first inverter circuit including third and fourth transistors coupled in series and each having a gate terminal coupled to a terminal of the first transistor; and
a second inverter circuit having an output coupled to the terminal of the first transistor, the second inverter circuit including fifth and sixth transistors coupled in series and each having a gate terminal coupled to the converter output.

19. The integrated circuit as defined in claim 17, further comprising:
a second stage level converter having an input coupled to the converter output, the second stage level converter including:
a seventh having a gate comprising the input coupled to the converter output and a source coupled to a second stage level converter output;
an eighth transistor having a gate coupled to an inverse of the converter output and a source coupled to a second stage level converter output;
at least a ninth transistor having a gate coupled to the second stage level converter output and a terminal coupled to a third voltage source; and
at least a tenth transistor having a gate coupled to a terminal of the seventh transistor and a terminal coupled to the third voltage source;
wherein the second stage level converter is configured such that a logic level of the converter output is accurately translated to the second stage level converter output after the second and third voltage sources are operable after being not operable.

20. The integrated circuit as defined in claim 19, further comprising:
an enable transistor having a terminal coupled to the terminals of the first and second transistors, another terminal coupled to a common potential, and a gate terminal coupled to an enable signal operable with the second voltage source, wherein operation of the level converter may be switched on and off by operation of the enable transistor.

21. The integrated circuit as defined in claim 19, further comprising:
at least one clocking transistor having a having a terminal coupled to terminals of the first and second transistors, another terminal coupled to a common potential, and a gate coupled to a clock signal operable with the third voltage source, wherein operation of the level converter may be switched on and off by operation of the at least one clocking transistor.

22. The integrated circuit as defined in claim 18, wherein the first, second, fourth and sixth transistors are NMOS transistors, and the third and fifth transistors are PMOS transistors.

23. A method for converting a signal between two voltage domains comprising:
receiving a signal operable at a first voltage level of a first voltage domain of an integrated circuit;
converting the signal to a second voltage level and outputting the converted signal to a second voltage domain of the integrated circuit; and
maintaining a voltage state of the converted signal when a first voltage source supplying voltage to the first voltage domain is not operable by using a second voltage source supplying voltage to the second voltage domain.

24. A method as defined in claim 23, further comprising:
maintaining the voltage state of the converted signal when the first voltage source and the source are not operable through the use of a third voltage source.
